(19) United States
(12) Patent Application Publication
(10) Pub. No.: US 2024/0258004 A1
(43) Pub. Date: Aug. 1, 2024

(54) SUPERCONDUCTING MAGNET DEVICE AND RADIATION SHIELD STRUCTURE

(71) Applicant: SUMITOMO HEAVY INDUSTRIES, LTD., Tokyo (JP)

(72) Inventors: Jyun YOSHIDA, Yokosuka-shi (JP); Takaaki MORIE, Yokosuka-shi (JP); Kenta DEMURA, Yokosuka-shi (JP)

(73) Assignee: SUMITOMO HEAVY INDUSTRIES, LTD., Tokyo (JP)

(21) Appl. No.: 18/604,421

(22) Filed: Mar. 13, 2024

Related U.S. Application Data
(63) Continuation of application No. PCT/JP2022/032227, filed on Aug. 26, 2022.

(30) Foreign Application Priority Data
Sep. 16, 2021 (JP) 2021-150843

(51) Int. Cl. H01F 6/04; H01F 6/06; H05K 9/00

(52) U.S. Cl. CPC H01F 6/04; H01F 6/06; H05K 9/0049

(57) ABSTRACT

A superconducting magnet device includes a superconducting coil; a radiation shield including a plurality of divided shield pieces disposed to surround the superconducting coil; a thermal bridge member that thermally connects the plurality of divided shield pieces to each other and is formed of a high thermal conductivity metal having a higher thermal conductivity than stainless steel; and a resistance layer that is interposed between the thermal bridge member and the divided shield pieces and has a higher electrical resistivity than the thermal bridge member.

### CROSS-REFERENCE TO RELATED APPLICATIONS

This is a bypass continuation of International PCT Application No. PCT/JP2022/032227, filed on Aug. 26, 2022, which claims priority to Japanese Patent Application No. 2021-150843, filed on Sep. 16, 2021, which are incorporated by reference herein in their entirety.

### BACKGROUND

### Technical Field

A certain embodiment of the present invention relates to a superconducting magnet device and a radiation shield structure.

### Description of Related Art

In general, a superconducting magnet device includes a vacuum container, a superconducting coil that is cooled to a cryogenic temperature in the vacuum container, and a radiation shield that surrounds the superconducting coil in the vacuum container. The radiation shield is cooled to a cryogenic temperature higher than a temperature of the superconducting coil in order to prevent input heat due to radiation from the vacuum container to the superconducting coil. The radiation shield is usually formed of a thin plate of a metallic material having a good thermal conductivity, such as copper. Since such a material usually has an excellent electrical conductivity, an eddy current is induced in the radiation shield by a fluctuation in acting magnetic field. In particular, in a case where quenching of the superconducting coil occurs, the magnetic field is abruptly changed, so that a large eddy current is induced, a large Lorentz force is generated due to interaction between the magnetic field and the eddy current, and there is a concern that the radiation shield may be deformed or damaged. Therefore, in the related art, it has been proposed to reduce eddy currents and Lorentz forces induced in individual divided portions by providing slits in the radiation shield to divide the radiation shield into a plurality of divided portions.

### SUMMARY

According to a certain aspect of the present invention, there is provided a superconducting magnet device including: a superconducting coil; a radiation shield including a plurality of divided shield pieces disposed to surround the superconducting coil; a thermal bridge member that thermally connects the plurality of divided shield pieces to each other and is formed of a high thermal conductivity metal having a higher thermal conductivity than stainless steel; and a resistance layer that is interposed between the thermal bridge member and the divided shield pieces and has a higher electrical resistivity than the thermal bridge member.

According to a certain aspect of the present invention, there is provided a radiation shield structure for a superconducting coil, including: a radiation shield including a plurality of divided shield pieces disposed to surround the superconducting coil; a thermal bridge member that thermally connects the plurality of divided shield pieces to each other and is formed of a high thermal conductivity metal having a higher thermal conductivity than stainless steel; and a resistance layer that is interposed between the thermal bridge member and the divided shield pieces and has a higher electrical resistivity than the thermal bridge member.

### BRIEF DESCRIPTION OF THE DRAWINGS

FIG. 1 is a diagram schematically showing a superconducting magnet device according to an embodiment.

FIG. 2 is a diagram schematically showing a connection portion of a divided structure of a radiation shield according to the embodiment.

### DETAILED DESCRIPTION

However, in the divided radiation shield, a temperature difference is likely to occur between the shield portions as compared to a non-divided radiation shield. This is because a divided portion having a long heat transfer path from a cooling source such as a cryocooler is less likely to be cooled than a divided portion having a short heat transfer path, and thus a temperature thereof is likely to increase. There is a concern that the shield portion having a relatively high temperature becomes a heat source, and the input heat to the superconducting coil increases. Therefore, the radiation shield having a divided structure is effective in reducing the Lorentz force as described above, but is less favorable than the radiation shield having an integral structure in an original role of reducing the input heat to the superconducting coil.

It is desirable to provide a radiation shield having a divided structure that reduces radiant heat entering a superconducting coil, and a superconducting magnet device including the radiation shield.

According to the certain aspect of the present invention, it is possible to provide a radiation shield having a divided structure that reduces radiant heat entering a superconducting coil, and a superconducting magnet device including the radiation shield.

Hereinafter, an embodiment for carrying out the present invention will be described in detail with reference to the drawings. In the description and drawings, the same or equivalent components, members, and processes are denoted by the same reference numerals, and overlapping descriptions are omitted as appropriate. The scales and shapes of the illustrated parts are set for convenience in order to facilitate explanation, and should not be construed in a limited manner unless otherwise specified. The embodiment is an example and does not limit the scope of the present invention. All features and combinations thereof described in the embodiment are not necessarily essential to the invention.

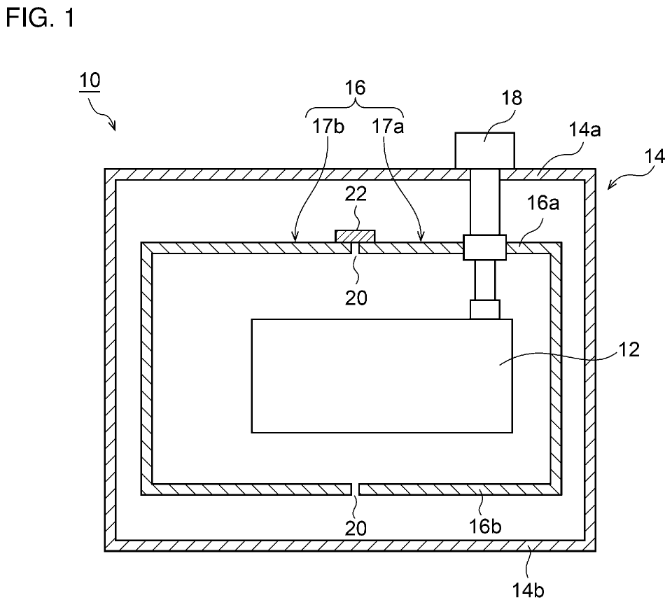

FIG. 1 is a diagram schematically showing a superconducting magnet device 10 according to an embodiment. The superconducting magnet device 10 can be mounted on a high-magnetic field utilization device as a magnetic field source of, for example, a single crystal pulling device, a nuclear magnetic resonance (NMR) system, a magnetic resonance imaging (MRI) system, an accelerator such as a cyclotron, a high energy physical system such as a nuclear fusion system, or other high-magnetic field utilization devices (not shown) and can generate a high magnetic field required for the device.

The superconducting magnet device 10 includes a superconducting coil 12, a vacuum container 14, a radiation shield 16, and a cryocooler 18.

The superconducting coil 12 is disposed in the vacuum container 14. The superconducting coil 12 is thermally coupled to the cryocooler 18, for example, a two-stage Gifford-McMahon (GM) cryocooler or other types of cryocoolers installed in the vacuum container 14, and is used in a state of being cooled to a cryogenic temperature equal to or lower than a superconducting transition temperature. In this embodiment, the superconducting magnet device 10 is configured as a so-called conduction cooling type in which the superconducting coil 12 is directly cooled by the cryocooler 18. Note that, in another embodiment, the superconducting magnet device 10 may be configured as an immersion cooling type in which the superconducting coil 12 is immersed in a cryogenic liquid refrigerant such as liquid helium.

The vacuum container 14 is an adiabatic vacuum container that provides a cryogenic vacuum environment suitable for bringing the superconducting coil 12 into a superconducting state, and is also called a cryostat. Typically, the vacuum container 14 has a columnar shape or a cylindrical shape with a hollow portion in a central portion thereof. Therefore, the vacuum container 14 includes substantially flat circular or annular top plate 14a and bottom plate 14b, and a cylindrical side wall (cylindrical outer peripheral wall, or coaxially disposed cylindrical outer peripheral wall and inner peripheral wall) connecting the top plate and the bottom plate. The cryocooler 18 may be installed on the top plate 14a of the vacuum container 14. The vacuum container 14 is formed of, for example, a metallic material such as stainless steel or other suitable high-strength materials to withstand an ambient pressure (for example, atmospheric pressure). In addition, a current introduction terminal (not shown) for supplying power from a coil power source disposed outside the vacuum container 14 to the superconducting coil 12 is provided in the vacuum container 14.

The radiation shield 16 is disposed to surround the superconducting coil 12 within the vacuum container 14. The radiation shield 16 includes a top plate 16a and a bottom plate 16b facing the top plate 14a and the bottom plate 14b of the vacuum container 14, respectively. The top plate 16a and the bottom plate 16b of the radiation shield 16 have substantially flat circular or annular shapes similar to the vacuum container 14. Further, the radiation shield 16 includes a cylindrical side wall (cylindrical outer peripheral wall or coaxially disposed cylindrical outer peripheral wall and inner peripheral wall) connecting the top plate 16a and the bottom plate 16b. The radiation shield 16 can block radiant heat from the vacuum container 14, and thermally protect a low-temperature section such as the superconducting coil 12, which is disposed inside the radiation shield 16 and cooled to a lower temperature than the radiation shield 16, from the radiant heat.

A first cooling stage of the cryocooler 18 is thermally coupled to the top plate 16a of the radiation shield 16, and a second cooling stage of the cryocooler 18 is thermally coupled to the superconducting coil 12 inside the radiation shield 16. During operation of the superconducting magnet device 10, the radiation shield 16 is cooled to a first cooling temperature, for example, 30K to 70K, by the first cooling stage of the cryocooler 18, and the superconducting coil 12 is cooled to a second cooling temperature lower than the first cooling temperature, for example, 3K to 20K (for example, about 4K) by the second cooling stage of the cryocooler 18.

The radiation shield 16 includes a plurality of, in this example, two divided shield pieces 17a and 17b, and the divided shield pieces 17a and 17b are separated from each other by slits (division lines) 20 and are disposed so as to surround the superconducting coil 12. Preferably, the radiation shield 16 is divided so as to cut off a path of an eddy current induced in the radiation shield 16 by a magnetic field generated by the superconducting coil 12. Accordingly, the eddy current induced in the individual divided shield pieces 17a and 17b are reduced compared to the eddy current that can be induced in the radiation shield having an integral structure. In a case where the radiation shield 16 has a cylindrical shape and a magnetic field acts in a direction perpendicular to a center axis thereof, the eddy current can be induced along a circumferential direction of the radiation shield 16 around the center axis. Therefore, the radiation shield 16 may be divided in the circumferential direction. The number of the divided shield pieces configuring the radiation shield 16 is not particularly limited.

The radiation shield 16 is formed of pure copper (for example, oxygen-free copper, tough pitch copper, or the like) in this example. For example, the pure copper may have a purity of 99.9% or more or 99.95% or more. Alternatively, the radiation shield 16 may be formed of pure aluminum (for example, having a purity of 99.5% or more). It is known that pure aluminum shows a higher thermal conductivity at a cryogenic temperature of 100 K or lower than in a temperature range higher than the cryogenic temperature, and the thermal conductivity increases as the temperature decreases to show a good thermal conductivity at a cryogenic temperature of 20 K or lower. Alternatively, the radiation shield 16 may be formed of a high thermal conductivity metal such as silver and gold, or other high thermal conductivity metals having a higher thermal conductivity than at least stainless steel.

The plurality of divided shield pieces 17a and 17b are thermally connected to each other by a thermal bridge member 22. The divided shield pieces 17a and 17b are thermally connected to each other only by the thermal bridge member 22, that is, the thermal bridge member 22 is the only thermal conduction path connecting the divided shield pieces 17a and 17b. The thermal bridge member 22 may be provided only in a part of the slits 20 that separate the plurality of divided shield pieces 17a and 17b, and the thermal bridge member 22 may not be provided in a remaining part of the slits 20. In the illustrated example, the thermal bridge member 22 connects the top plates 16a of the divided shield pieces 17a and 17b to each other. Therefore, the slit 20 of the bottom plate 16b is not bridged with the thermal bridge member 22. The thermal bridge member 22 is not provided in the slit 20 of the side wall of the radiation shield 16.

In a case where the cryocooler 18 is connected to the top plate 16a of one divided shield piece 17a, the thermal bridge member 22 can form a substantially shortest heat transfer path from the cryocooler 18 to the other divided shield piece 17b. This is helpful for efficiently cooling the other divided shield piece 17b that is away from the cryocooler 18, reducing a temperature difference between the divided shield pieces 17a and 17b, and uniformly cooling the radiation shield 16. In addition, since the top plate 16a is flat in this example, there is also an advantage in that the thermal bridge member 22 is easily attached as compared to a case where the thermal bridge member 22 is attached to the cylindrical side wall.

In addition, in other embodiments, the thermal bridge member 22 may connect the divided shield pieces 17a and 17b at the bottom plate 16b, or may connect the divided shield pieces 17a and 17b at the cylindrical side wall. Alternatively, a plurality of the thermal bridge members 22 may be provided, and the divided shield pieces 17a and 17b may be connected at a plurality of locations, for example, at the top plate 16a and the bottom plate 16b. Alternatively, the thermal bridge member 22 may extend over the entire length of the slit 20, and may connect the divided shield pieces 17a and 17b at the top plate 16a, the bottom plate 16b, and the side wall.

The thermal bridge member 22 is formed of a high thermal conductivity metal, for example, a high thermal conductivity metal having a higher thermal conductivity than stainless steel. The thermal bridge member 22 may be formed of a material having a coefficient of thermal expansion equal to or similar to that of the divided shield pieces 17a and 17b, for example, the same high thermal conductivity metal as the divided shield pieces 17a and 17b, such as pure copper or pure aluminum. In this way, coefficients of thermal expansion of the thermal bridge member 22 and the divided shield pieces 17a and 17b can be matched with each other. Therefore, it is possible to minimize a thermal stress that can occur between the thermal bridge member 22 and the divided shield pieces 17a and 17b due to cryogenic cooling.

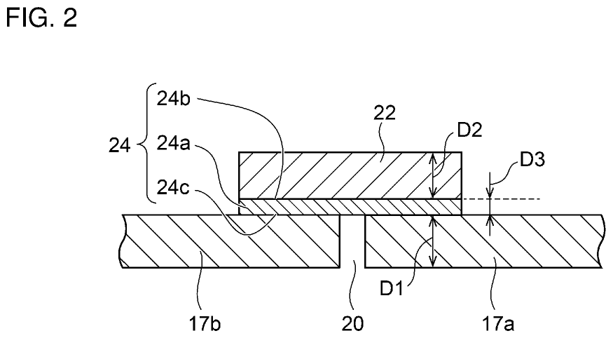

FIG. 2 is a diagram schematically showing a connection portion of a divided structure of the radiation shield 16 according to the embodiment. The connection portion of the divided structure includes a metal sheet 24 interposed between the divided shield pieces 17a and 17b and the thermal bridge member 22. The metal sheet 24 is covered with a resistance layer having a higher electrical resistivity than the thermal bridge member 22 on a surface of a main body 24a thereof, and includes an upper resistance layer 24b and a lower resistance layer 24c. The upper resistance layer 24b forms a contact interface between the thermal bridge member 22 and the metal sheet 24, and the lower resistance layer 24c forms a contact interface between the divided shield pieces 17a and 17b and the metal sheet 24.

In this embodiment, the metal sheet 24 is, for example, a stainless steel sheet. A member formed of stainless steel generally has a passive film on a surface thereof. The surface of the metal sheet 24 is covered with a passive film. Therefore, the upper resistance layer 24b and the lower resistance layer 24c are the passive films. The material of the metal sheet 24 is not limited to stainless steel. For example, the metal sheet 24 may be formed of other metallic materials that form a passive film on a surface thereof, such as aluminum and chromium.

The metal sheet 24 includes the upper resistance layer 24b and the lower resistance layer 24c, and a plurality of (in this example, two) resistance layers are provided between one divided shield piece 17a and the thermal bridge member 22. When the eddy current flows from the divided shield piece 17a to the thermal bridge member 22, since the resistance layers are connected in series, an effect of suppressing the eddy current is increased as compared to a case where there is only one resistance layer.

The thermal bridge member 22 and the divided shield pieces 17a and 17b are mechanically fixed to each other using a fastening member such as a bolt, for example, with the metal sheet 24 interposed therebetween. In a case where applicable, the thermal bridge member 22 and the divided shield pieces 17a and 17b may be fixed to each other by an appropriate fixing method such as welding or bonding.

In order to further improve a thermal contact between the divided shield pieces 17a and 17b and the thermal bridge member 22, a grease having a good thermal conductivity may be applied between the divided shield pieces 17a and 17b and the metal sheet 24 and/or between the thermal bridge member 22 and the metal sheet 24.

A thickness D1 of the divided shield pieces 17a and 17b is typically in the order of millimeters, and is, for example, about 5 to 10 mm for the top plate 16a and the bottom plate 16b, and may be, for example, about 1 to 3 mm for the side wall of the radiation shield 16. A thickness D2 of the thermal bridge member 22 may be approximately the same as the thickness D1 of the divided shield pieces 17a and 17b.

In contrast, a thickness D3 of the metal sheet 24 is smaller than the thickness D1 of the divided shield pieces 17a and 17b and/or the thickness D2 of the thermal bridge member 22. In fact, in order to improve a thermal conductivity between the divided shield pieces 17a and 17b via the thermal bridge member 22, it is preferable that the thickness D3 of the metal sheet 24 is as thin as possible, and the thickness D3 may be, for example, 200 μm at the thickest, and may be, for example, about 20 μm to 100 μm. The upper resistance layer 24b and the lower resistance layer 24c are the passive films on the metal sheet 24, and thus are further thin, and are typically in the order of nanometers, and may be, for example, about 1 to 10 nm.

According to the embodiment, the divided shield pieces 17a and 17b are structurally connected to each other via the thermal bridge member 22, but the upper resistance layer 24b and the lower resistance layer 24c are interposed between the divided shield pieces 17a and 17b and the thermal bridge member 22. The upper resistance layer 24b and the lower resistance layer 24c are passive films, and have electrical resistance sufficient to prevent (or reduce) the eddy current flowing from the divided shield pieces 17a and 17b to the thermal bridge member 22.

According to a simulation by the present inventors, it is confirmed that a magnitude of an eddy current induced in the radiation shield 16 by a magnetic field fluctuation that may occur in accordance with the specifications of the superconducting magnet device 10 is approximately the same in the present embodiment (a shield divided structure having the thermal bridge member 22) and a comparative example (a shield divided structure without a thermal bridge in the related art). That is, the present embodiment can provide about the same eddy current reduction effect as the existing divided structure.

Accordingly, the superconducting magnet device 10 according to the embodiment can reduce the eddy current and the Lorentz force generated due to a magnetic field fluctuation such as quenching of the superconducting coil, and can reduce a risk of deformation or damage of the radiation shield 16 caused by the Lorentz force.

Since the metal sheet 24 is sufficiently thin, an influence on a thermal conductance between the divided shield pieces 17a and 17b and the thermal bridge member 22 is not significant or can be ignored. The thicknesses of the upper resistance layer 24b and the lower resistance layer 24c are extremely small, and substantially do not affect heat transfer between the divided shield pieces 17a and 17b and the thermal bridge member 22. According to the simulation by the present inventors, it is confirmed that a temperature rise of the adjacent divided shield piece with respect to a cooling temperature of the divided shield piece directly coupled to the cryocooler 18 is practically sufficiently reduced in the present embodiment (the shield divided structure having the thermal bridge member 22) as compared to the comparative example (the shield divided structure without the thermal bridge in the related art). Although the present embodiment has the radiation shield 16 having a divided structure, the entire radiation shield 16 can be uniformly cooled similarly to the radiation shield having an integral structure.

In this way, the radiation shield 16 can be regarded as having a divided structure from the viewpoint of electrical conductivity, and can be regarded as having an integral structure from the viewpoint of thermal conduction. Therefore, according to the embodiment, it is possible to provide the radiation shield 16 having the divided structure and the superconducting magnet device 10 including the radiation shield 16, which can achieve both countermeasures for the eddy current and uniformization of a temperature distribution under cryogenic cooling and suppress radiant input heat to the superconducting coil 12.

As another comparative example, a configuration in which a sheet-like insulating resin (for example, a polyimide sheet) is used as the thermal bridge member is also conceivable. However, such an insulating resin layer generally has a large thermal resistance and does not contribute to the improvement of the temperature distribution between the divided shields. Even in a case where the thermal bridge member is formed of stainless steel, the stainless steel has a considerably lower thermal conductivity than a suitable high thermal conductivity metal such as pure copper, and the temperature distribution is not improved. It is also conceivable to form the thermal bridge member using an insulating material having a good thermal conductivity (for example, aluminum nitride or the like). However, such an insulating material is likely to crack and is difficult to handle. There is also a mismatch in a thermal shrinkage rate with the radiation shield material, and thus such an insulating material is difficult to use.

The present invention has been described above based on the examples. It will be understood by those skilled in the art that the present invention is not limited to the above-described embodiment, and that various modifications are possible, and such modifications are also within the scope of the present invention. Various features described in relation to the certain embodiment are also applicable to other embodiments. A new embodiment generated by combination of the embodiments has effects of each of the embodiments to be combined.

In the above-described embodiment, mounting of the resistance layer to the connection portion of the shield divided structure has been described using the metal sheet 24 having the passive film as an example. However, other configurations are also possible. In a certain embodiment, a resistance layer, for example, a passive film may be formed on the surface of the thermal bridge member 22 itself. For example, the main body of the thermal bridge member 22 is formed of a high thermal conductivity metal such as pure copper as described above, and a metal layer (for example, a plating layer) that forms a passive film of stainless steel, aluminum, chromium, or the like may be formed on the surface of the main body. In this way, when the thermal bridge member 22 is fixed to the divided shield pieces 17a and 17b, the passive film can be interposed between the thermal bridge member 22 and the divided shield pieces 17a and 17b. Therefore, it is not essential to interpose the metal sheet 24 between the thermal bridge member 22 and the divided shield pieces 17a and 17b.

Although the present invention has been described using specific terms based on the embodiment, the embodiment only shows one aspect of the principle and application of the invention, and the embodiment allows for many modifications and changes in arrangement without departing from the concept of the invention as defined in the claims.

### INDUSTRIAL APPLICABILITY

The present invention can be used in the field of superconducting magnet devices and radiation shield structures.

It should be understood that the invention is not limited to the above-described embodiment, but may be modified into various forms on the basis of the spirit of the invention. Additionally, the modifications are included in the scope of the invention.

What is claimed is:

1. A superconducting magnet device comprising:
a superconducting coil;
a radiation shield including a plurality of divided shield pieces disposed to surround the superconducting coil;
a thermal bridge member that thermally connects the plurality of divided shield pieces to each other and is formed of a high thermal conductivity metal having a higher thermal conductivity than stainless steel; and
a resistance layer that is interposed between the thermal bridge member and the divided shield pieces and has a higher electrical resistivity than the thermal bridge member.

2. The superconducting magnet device according to claim 1,
wherein the resistance layer is a passive film.

3. The superconducting magnet device according to claim 2, further comprising a metal sheet having the passive film on a surface thereof and interposed between the thermal bridge member and the divided shield pieces.

4. The superconducting magnet device according to claim 3,
wherein the metal sheet is formed of stainless steel, aluminum, or chromium.

5. The superconducting magnet device according to claim 1,
wherein the divided shield pieces are also formed of the high thermal conductivity metal.

6. The superconducting magnet device according to claim 1,
wherein the high thermal conductivity metal is pure copper or pure aluminum.

7. The superconducting magnet device according to claim 1,
wherein the superconducting magnet device includes a plurality of the resistance layers interposed between the thermal bridge member and the divided shield pieces and having a higher electrical resistivity than the thermal bridge member.

8. A radiation shield structure for a superconducting coil, comprising:
a radiation shield including a plurality of divided shield pieces disposed to surround the superconducting coil;
a thermal bridge member that thermally connects the plurality of divided shield pieces to each other and is formed of a high thermal conductivity metal having a higher thermal conductivity than stainless steel; and
a resistance layer that is interposed between the thermal bridge member and the divided shield pieces and has a higher electrical resistivity than the thermal bridge member.
